(19) United States
(12) Patent Application Publication
(10) Pub. No.: US 2013/0307521 A1
(43) Pub. Date: Nov. 21, 2013

(54) STRAIN RELIEVING FEATURE FOR PRINTED CIRCUIT BOARD ASSEMBLIES

(71) Applicant: Brian Matthew Aiken, Smyrna, GA (US)

(72) Inventor: Brian Matthew Aiken, Smyrna, GA (US)

(73) Assignee: GENERAL ELECTRIC COMPANY, Schenectady, NY (US)

(21) Appl. No.: 13/475,876

(22) Filed: May 18, 2012

(51) Int. Cl. G01R 19/00; H05K 1/00; H02B 1/26

(52) U.S. Cl. 324/76.11; 361/659; 174/254

(57) ABSTRACT

A system includes a utility meter with a first conductive member and a circuit board coupled to the first conductive member at a first joint. The first joint is disposed along a first elongated strip portion of the circuit board. The first elongated strip portion is configured to flex relative to a main portion of the circuit board in response to thermal expansion or thermal contraction of the first conductive member or a component coupled to the first conductive member.

### BACKGROUND OF THE INVENTION

The subject matter disclosed herein relates to reducing stress within a circuit board, such as a circuit board within a utility meter.

Circuit boards mechanically support and electrically couple components of electrical devices. Electrical devices (e.g., utility meters) may be used for many purposes, including the measurement, processing, and communication of electrical signals. Utility meters incorporate many functionalities relating to the consumption of a utility such as water, electricity, and gas, to name a few. For example, utility meters may enable a utility provider, such as an electricity provider, to measure a consumer's use of the utility and communicate the use to the utility provider. Various components may be disposed within the utility meter to monitor usage, communicate with the utility provider, display information, or provide additional functionalities to the utility meter. These components may be coupled to one or more circuit boards within the utility meter. Operating conditions (e.g., environment, input signals) may produce heat and impose stresses on the one or more circuit boards and coupled components. The coupled components may respond to the operating conditions differently than the one or more circuit boards. Moreover, conditions such as temperature may not uniformly affect the circuit board and coupled components. Stresses on the circuit board or components may affect the functionality (e.g., accuracy) and reliability of the components.

### BRIEF DESCRIPTION OF THE INVENTION

Certain embodiments commensurate in scope with the originally claimed invention are summarized below. These embodiments are not intended to limit the scope of the claimed invention, but rather these embodiments are intended only to provide a brief summary of possible forms of the invention. Indeed, the invention may encompass a variety of forms that may be similar to or different from the embodiments set forth below.

In a first embodiment, a system includes a utility meter with a first conductive member and a circuit board coupled to the first conductive member at a first joint. The first joint is disposed along a first elongated strip portion of the circuit board. The first elongated strip portion is configured to flex relative to a main portion of the circuit board in response to thermal expansion or thermal contraction of the first conductive member or a component coupled to the first conductive member.

In a second embodiment, a system includes a circuit board configured to couple to a first conductive member at a first joint. The first joint is disposed along a first elongated strip portion of the circuit board. The first elongated strip portion is configured to flex relative to a main portion of the circuit board in response to thermal expansion or thermal contraction of the first conductive member or a component coupled to the first conductive member.

In a third embodiment, a method includes flexing a first elongated strip portion of a circuit board relative to a main portion of the circuit board in response to thermal expansion or thermal contraction of a first conductive member or a component coupled to the first conductive member. The first conductive member is coupled to the first elongated strip portion at a first joint.

### BRIEF DESCRIPTION OF THE DRAWINGS

These and other features, aspects, and advantages of the present embodiments will become better understood when the following detailed description is read with reference to the accompanying drawings in which like characters represent like parts throughout the drawings, wherein:

FIG. 1 is a block diagram of an embodiment of an electrical system in which utility meters may monitor utility consumption by various consumers;

FIG. 2 is a front perspective cut-away view of an embodiment of a utility meter having a circuit board with an elongated strip portion;

FIG. 3 is a perspective view of an embodiment of a circuit board coupled to a conductive member at joints along elongated strip portions;

FIG. 4 is a front view of an embodiment of an elongated strip portion surrounded by opposing slots; and

FIG. 5 is a front view of an embodiment of a cantilevered elongated strip portion.

### DETAILED DESCRIPTION OF THE INVENTION

One or more specific embodiments of the present invention will be described below. In an effort to provide a concise description of these embodiments, all features of an actual implementation may not be described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present embodiments, the articles “a,” “an,” “the,” and “said” are intended to mean that there are one or more of the elements. The terms “comprising,” “including,” and “having” are intended to be inclusive and mean that there may be additional elements other than the listed elements.

A circuit board and supporting components coupled to the circuit board within a utility meter may not be at the same temperature. Changes in temperature may induce thermal stresses that expand or contract the circuit board and supporting components. A conductive member of a component may be coupled to the circuit board at a joint (e.g., solder joint) to complete an electrical connection between the component and the circuit board. The circuit board and any coupled components may warm during use; however, the circuit board and coupled components may thermally expand and thermally contract in different amounts, at different rates, and/or in different directions. In presently contemplated embodiments, the conductive member is coupled to the circuit board at the joint disposed along an elongated strip portion of the circuit board. The elongated strip portion is configured to flex relative to a main portion of the circuit board to enable the thermally induced stresses to displace the joints without causing the joints and/or circuit board to fail (e.g., crack, fracture, decouple). The elongated strip portion may be a cantilevered portion within the circuit board or protruding from an edge of the circuit board. Slots may surround one or more sides of the joint and the elongated strip portion to provide space for the joint and elongated strip portion to be displaced, for example, due to thermally induced stresses. In some embodiments, the circuit board may have multiple elongated strip portions, each coupled to joints wherein each elongated strip portion is configured to flex relative to the main portion of the circuit board in response to thermally induced stresses. Thus, the elongated strip portions may be configured to absorb any displacement caused by thermal expansion or thermal contraction, vibration, shock, or other motion, thereby protecting the circuit board and its components. The component coupled to the circuit board by one or more conductive members may be a sensor (e.g., ammeter) or a heating element.

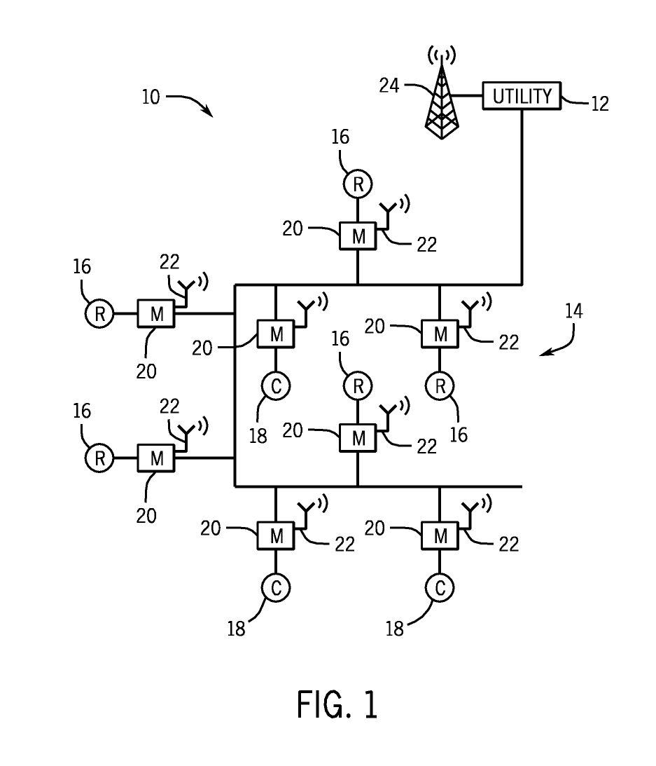

With the foregoing in mind, FIG. 1 represents a block diagram of a utility system 10, which includes a utility 12 connected to a distribution grid 14. The utility may distribute electricity, water, or gas to consumers, such as residential establishments 16 and commercial establishments 18. In electrical system 10, the utility 12 may be a power utility that supplies power to a power grid 14. In the electrical system, the residential 16 and commercial 18 establishments may be loads on the power grid 14. Utility meters 20 on the distribution grid 14 may monitor the utility consumption by the residential establishments 16 or commercial establishments 18. In a normal operational state, the utility meters 20 may monitor consumption by the residential establishment 16 or the commercial establishment 18 to which they are affixed. Additionally, the utility meters 20 may communicate with the utility 12 via data communication links 22. Such data communication links 22 may be wired (e.g., over wired telecommunication infrastructure or distribution grid 14) or wireless (e.g., a cellular network or other wireless broadband, such as WiMax). Similarly, the utility 12 may employ a communication link 24 to communicate with the various utility meters 20. The communication link 24 may be wired or wireless, as may be suitable to communicate to the various communication links 22 of the utility meters 20.

The utility meters 20 may take a variety of forms. It should be noted that while the disclosed embodiments discussed below are in the context of conductive assemblies within an electric meter, other types of utilities are also presently contemplated. For example, meters in accordance with the disclosed embodiments may monitor any one or a combination of electricity, heat, gas, water, or any other utility. Therefore, while the disclosed embodiments are presented in the context of electric meters, other utility meters, such as heat meters, gas meters, water meters, or any combination thereof, are presently contemplated. Furthermore, energy meters, as presently discussed, may include gas meters, electricity meters, or a combination thereof. The conductive assemblies described below may also be used for other electronic devices beyond utility meters.

As mentioned above and described in greater detail below, the utility meters 20 may include various components within an enclosure. The components may be coupled at joints (e.g., solder joints) to a circuit board within the utility meter 20. Some electrical components that conduct electricity may warm due to electrical resistance. Changes in temperature may cause the components and circuit board to contract or expand, which may increase stress on the components, joints, and the circuit board. Additionally, the components and circuit board may not contract or expand the same amount, at the same rate, or in the same direction. Differential thermal expansion may further increase the stress on the components, joints and the circuit board. Accordingly, the disclosed embodiments provide a resilient coupling integrally formed as part of the utility meter 20 circuit board 26.

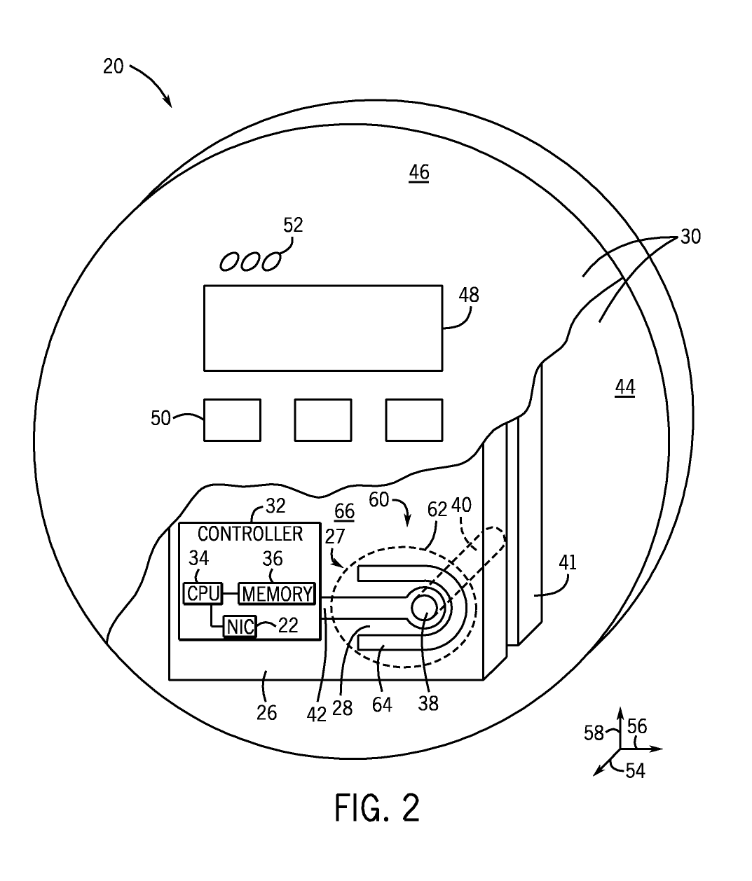

FIG. 2 illustrates a cut-away front perspective view of an embodiment of a utility meter 20 having a circuit board 26 with a resilient coupling 27 having an elongated strip portion 28. The circuit board 26 may be enclosed within a housing 30 of the utility meter 20. In some embodiments, the circuit board 26 may have electrical components such as a controller 32, a processor 34, and a memory 36. The processor 34 and memory 36 may be separate from or within the controller 32. The elongated strip portion 28 may have a joint 38 that couples a conductive member 40 to the circuit board 26. In some embodiments, the conductive member 40 may be coupled to a second circuit board 41 or the distribution grid 14 (FIG. 1). The conductive member 40 may extend through the housing base 44 or housing cover 46 to couple with components outside the utility meter 20. Some examples of the conductive member 40 include a terminal blade that conducts electricity with the distribution grid 14, a sensor terminal to measure an electrical signal, a heating element, or an antenna.

In some embodiments, electrical components coupled to the circuit board 26 may be used to measure electrical signals conducted through the conductive member 40. Electricity conducted through the conductive member 40 is also conducted through the joint 38 (e.g., solder joint) and bar 42. The bar 42 may be electrically coupled to the controller 32 or the processor 34 to transmit electrical signals between the conductive member 40 and the controller 32 or processor 34. In some embodiments, the controller 32 receives an electrical signal through the bar 42 and measures utility usage or other properties that may be derived from the electrical signal. The processor 34 may analyze the electrical signal, determine utility usage properties from the electrical signal, store information related to the utility usage in memory 36, and/or transmit information to the utility through a communication link 22 (e.g., network interface card (NIC)).

In some embodiments, the conductive member 40 may be part of an ammeter used to measure current. In an electricity meter, the current may directly relate to the power usage. For a gas or water meter, other sensors (e.g., flow meters) measuring the utility usage may produce the electrical signal that passes through the conductive member 40. The processor 34 may determine utility usage based at least in part on the electrical signal through received from the conductive member 40. In some embodiments, the housing 30 may have the cover 46 with a display 48, inputs 50, and/or indicators 52. The controller 32 may display utility usage or other properties on the display 48, which may be digital or analog. The one or more inputs 50 may enable an operator to change operational mode (e.g., units of measure) or access information stored in memory 36. Indicators 52 may show the operational status (e.g., on/off, utility interruption) of the utility meter 20.

In other embodiments, the conductive member 40 may be a heating element. The heating element conductive member 40 may be within the utility meter 20 or within another electronic device. The controller 32 may control an electrical current through the conductive member 40 to warm the conductive member 40. The warm conductive member 40 may be used to warm the environment surrounding the electronic device. A warmed environment may improve the operation of the electronic device. For example, sensors within the electronic device (e.g., utility meter) may operate most efficiently within a certain temperature range. The controller 32 may warm the conductive member 40 when the ambient temperature drops below the certain temperature range.

As the temperature of the parts within the utility meter 20 changes, the conductive member 40 and/or components coupled to the conductive member 40 may expand or contract. As indicated by the legend, arrow 54 indicates a vertical Y-axis relative to the circuit board 26, arrow 56 indicates a horizontal X-axis along the circuit board 26, and arrow 58 indicates a horizontal Z-axis along the circuit board 26. In some embodiments, the conductive member 40 extends substantially parallel to the Y-axis 54 and perpendicular to the circuit board 26. In an embodiment, the conductive member 40 may extend substantially parallel to the Z-axis 58 and the circuit board 26. Various embodiments of the utility meter may include the conductive member 40 extending from the joint 38 along the Y-axis 54, the X-axis 56, or the Z-axis 58, or any combination thereof. The conductive member 40 may be displaced along one or more of the axes 54, 56, 58 by the thermal expansion or thermal contraction of the conductive member or component coupled thereto. A conductive assembly 60 includes the conductive member 40 and any component coupled thereto, the joint 38, the bar 42, and a region 62 of the adjoining circuit board 26. The region 62 may include one or more elongated strip portions 28 and one or more slots 64. The circuit board 26, particularly the region 62, may not be displaced the same amount at the same rate or in the same direction as the conductive member 40 when both are at a certain temperature. This differential thermal expansion and thermal contraction may induce thermal stresses on the circuit board 26 and the conductive assembly 60.

In the present embodiments, the conductive assembly 60 includes the one or more slots 64 that define the elongated strip portion 28. The conductive member 40 is coupled to the elongated strip portion 28 at the joint 38. As the conductive member 40 or component coupled thereto expands and contracts, the coupled elongated strip portion 28 flexes due to the displacement of the joint 38. The slots 64 in the circuit board 26 may increase the flexibility of the circuit board 26. The slots 64 may also provide space for the elongated strip portion 28 to flex along the one or more axes 54, 56, and 58 relative to a main portion 66 of the circuit board 26 depending on the disposition of the slots 64. For example, in the illustrated embodiment shown in FIG. 2, the elongated strip portion 28 may be configured to flex along at least the Y-axis 54 and the Z-axis 58. Thus, the elongated strip portion 28 may be configured to flex relative to the main portion 66 in response to thermal expansion or contraction of the conductive member 40 or components coupled thereto. The one or more slots 64 may substantially isolate the flexing of the elongated strip portion 28 from the main portion 66 of the circuit board 26. This may reduce the thermally induced stress on the circuit board 26 and joint 38.

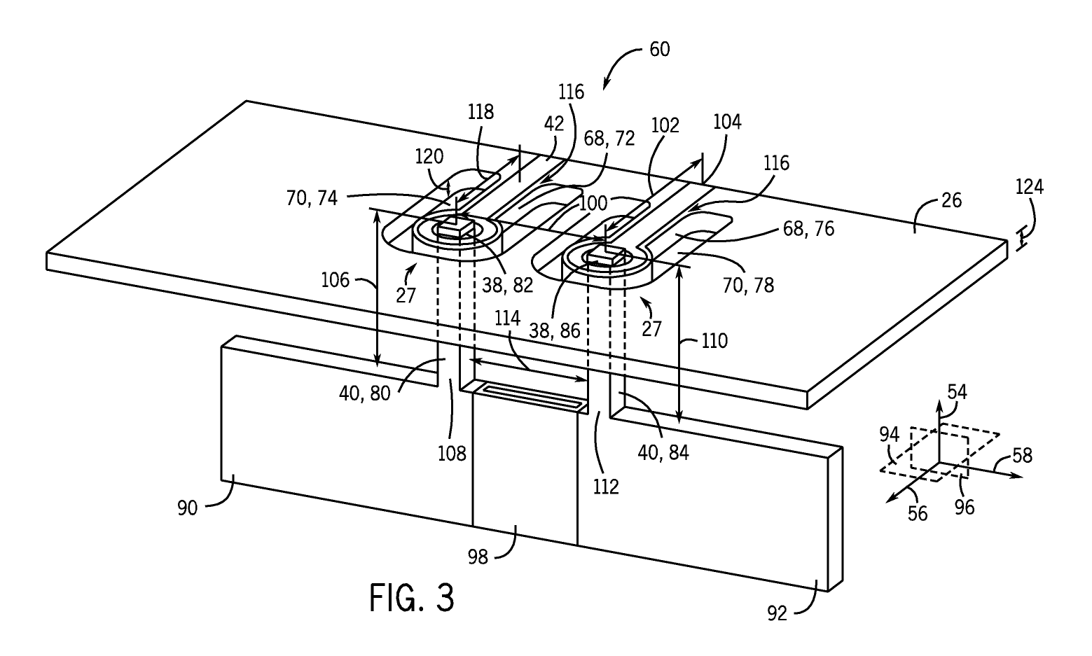

FIG. 3 illustrates a profile perspective view of an embodiment of a circuit board 26 and two conductive assemblies 60, each having a resilient coupling 27. In the illustrated embodiment, the circuit board 26 has two cantilevered portions 68 surrounded by U-shaped slots 70 to define the resilient couplings 27. The first cantilevered portion 72 is surrounded by the first U-shaped slot 74, and the second cantilevered portion 76 is surrounded by the second U-shaped slot 78. As described above with FIG. 2, the conductive members 40 may be a part of a sensor (e.g., ammeter shunt) or a heating element, among others. In an embodiment, a first conductive member 80 is coupled to the first cantilevered portion 72 at a first joint 82, and a second conductive member 84 is coupled to the second cantilevered portion 76 at a second joint 86. The first and second conductive members 80, 84 may electrically couple a component 88 to the circuit board 26. The component 88 (e.g., resistor, sensor, heating element, antenna) may be electrically coupled to the first and second conductive members 80, 84 with first and second conductive leads 90, 92. In some embodiments, the first conductive member 80 may be the first conductive lead 90 and the second conductive member 84 may be the second conductive lead 92. Electrical signals may pass from the component 88 to the circuit board 26, from the circuit board 26 to the component 88, or any combination thereof. For example, in an embodiment where the component 88 is a resistor and the first and second conductive members 80, 84 are part of a shunt, a fraction of the current flowing through the first conductive lead 90 may flow through the first conductive member 80 to the circuit board 26 and through the second conductive member 84 to the second conductive lead 92. In an embodiment where the component 88 is a heating element, current may flow from the circuit board 26 through the first conductive member 80 to a resistor component 88 and back to the circuit board 26 through the second conductive member 84.

In some embodiments as illustrated in FIG. 3, the first and second conductive members 80, 84 may be substantially parallel to the Y-axis 54 and perpendicular to the circuit board 26. The circuit board 26 may substantially lie along the XZ plane 94. The first and second conductive leads 90, 92 may be substantially perpendicular to the circuit board 26 and lie along the YZ plane 96. The component 88 may include the first and second conductive members 80, 84, the first and second conductive leads 90, 92, and a resistive portion 98 coupled between the first and second conductive leads 90 92. As used herein, the phrase “the conductive member 40 or components coupled thereto” includes the component 88. The resistive portion 98 may be a precision resistor material of copper, manganese, nickel, or other metals or combinations thereof. In an embodiment, the precision resistor material may be an alloy with approximately 86% by mass copper, approximately 12% by mass manganese, and approximately 2% by mass nickel. For example, the first and second conductive members 80, 84 may be part of an ammeter shunt. Electrical components (e.g., controller 32) on the circuit board 26 electrically coupled to the first and second conductive members 80, 84 may measure and use the voltage drop across the resistive portion 98 to determine the current passing through the component 88. The determined current may be used to determine utility usage.

In an embodiment, during operation at room temperature (e.g., between 20 to 25 degrees Celsius), the conductive assembly 60 may be in a first configuration where the first and second joints 82, 86 are a first horizontal distance 100 apart, one or both the first and second joints 82, 86 are a second horizontal distance 102 from a point 104 (e.g., edge) of the main portion 66 of the circuit board 26, and the first and second cantilevered portions 72, 76 lie within the XZ plane 94 of the circuit board 26. In the first configuration, the first joint 82 is a first vertical distance 106 from a first base 108, the second joint 86 is a second vertical distance 110 from a second base 112, and the first and second bases 108, 112 are set apart a third horizontal distance 114.

An electrical current may warm one or more parts of the component 88 or circuit board 26 through resistive heating. Warmed parts may undergo thermal expansion, and cooled parts may undergo thermal contraction. Thermal expansion may cause parts to expand along one or more axes 54, 56, and 58, whereas thermal contraction may cause parts to contract or shrink along one or more axes 54, 56, and 58. A part with a large resistance (e.g., resistive portion 98) may warm more than a part with a small resistance (e.g., conductive member 40). In some embodiments, thermal expansion of the resistive portion 98 may displace the first and second conductive leads 90, 92, the first and second conductive members 80, 84, or the first and second joints 82, 86 or any combination thereof. Thermal expansion or contraction may change the configuration of the conductive assembly 60 from the first configuration. For example, thermal expansion of the resistive portion 98 along the Z-axis 58 may increase the first horizontal distance 100 and/or the third horizontal distance 114. Increasing the first horizontal distance 100 displaces at least one of the first and second joints 82, 86 from the first configuration. This may horizontally flex the first and/or second cantilevered portions 72, 76 outward (i.e., away from one another) along the Z-axis 58. Accordingly, the resilient couplings 27 may also be described as shock absorbers.

Thermal expansion or contraction may also affect parts of the conductive assembly 60 in other ways. For example, warmed first and second conductive members 80, 84 may thermally expand, changing the first and/or second vertical distances 106, 110. This may vertically displace the first and/or second joints 82, 86 along the Y-axis 54 and flex the cantilevered portions 72, 76 vertically along the Y-axis 54 from the first configuration. Thermal expansion or contraction of the first or second conductive members 80, 84 may cause the first or second cantilevered portions 72, 76 to not lie within the XZ plane 94 of the circuit board 26 as in the first configuration. In some embodiments, the resistive portion 98, first conductive member 80, and second conductive member 84 may thermally contract. Thermal contraction of the resistive portion 98 may decrease the third horizontal distance 114 causing the first and second cantilevered portions 72, 76 to flex towards one another along the Z-axis 58. Thermal contraction of the first and second conductive members 80, 84 may decrease the first and second vertical distances 106, 110 causing the first and second cantilevered portions 72, 76 to flex vertically downward along the Y-axis 54 towards the resistive portion 98.

Each part (e.g., cantilevered portion 68) of the circuit board 26 and parts (e.g., conductive member 40) coupled to the circuit board 26 may be subject to different temperatures during operation or storage. At any time, some parts of the conductive assembly 60 or component 88 may thermally expand due to increased temperatures while other parts thermally contract due to decreased temperatures. The conductive assembly 60 and component 88 may be configured to operate within a temperature range of approximately −40 to 65, −20 to 45, 0 to 30, or 10 to 25 degrees Celsius. In some embodiments, temperature differentials between parts may be between 0 to 50, 0 to 25, or 0 to 10 degrees Celsius. In some embodiments, the resistive portion 98 may become warmer and expand more than the cooler conductive members 40.

The elongated strip portions (e.g., cantilevered portions 68) and slots (e.g., U-shaped slots 70) may be configured to increase the flexibility of the circuit board 26 and reduce stress within the circuit board 26. Thermal expansion or thermal contraction of the conductive assembly 60 or component 88 induces stress within the circuit board 26. For example, thermal expansion of the resistive portion 98 places stress at the first and second bases 108, 112 of the conductive members 40 to increase the third horizontal distance 114. This thermally induced stress on the conductive members 40 may displace the first and second bases 108, 112 and cause the conductive members to place thermally induced stresses on the joints 38 and elongated strip portions 28. These thermally induced stresses may displace the joints 38 and elongated strip portions 28, and place stresses on the joints 38 and strip roots 116 of the elongated strip portions 28. Large stresses (i.e., failure stresses) may weaken or break the electrical connection (e.g., solder connection) at the joints 38 and/or strip roots 116. In some embodiments, the root 116 may have a higher strength than the joint 38.

The geometry of the elongated strip portions 28 and the slots 64 may reduce or distribute large stresses to reduce the possibility of weakening or severing of the electrical connections. One or more slots 64 increase the flexibility of the surrounded elongated strip portion 28 relative to the main portion 66 of the circuit board 26. The slots 64 provide space for the elongated strip portion 28 to be displaced along one or more of the axes 54, 56, 58. The elongated strip portion 28 may enable the thermally induced stress from the conductive member 40 to be distributed along the length 118. Distributing the stress across the length 118 may reduce the stress at the joint 38 and root 116. Reducing the stress may increase the fatigue life of the elongated strip portion 28 and/or the joint 38 (e.g., solder joint). The elongated strips 38 and slots 64 passively reduce stress and increase the flexibility of the circuit board 26. The length 118 and thickness 120 of the elongated strip portion 28 affects the flexibility. Flexible elongated strip portions 28 may be configured to displace along one or more of the axes 54, 56, 58 so that the thermally induced stress may be distributed along the elongated strip portion 28 and joint 38, rather than just at the joint 38. Increasing the length 118 and decreasing the thickness 120 increases the flexibility, whereas decreasing the length 118 and increasing the thickness 120 decreases the flexibility. For example, a long and thin elongated strip portion 28 may be displaced a certain amount within the slot 64 without failure of the joint 38, whereas a joint in the main portion 66 of the circuit board 26 without an elongated strip portion (i.e., no length 118 or slot 64) displaced the certain amount may fail.

The elongated strip portion 28 may have different geometries and configurations. In some embodiments the elongated strip portion 28 is integral with the circuit board 26. In some embodiments, the elongated strip portion 28 may be coupled to the circuit board 26. For example, an elongated strip portion 28 may be coupled (e.g., soldered, bolted) to the circuit board 26 to increase the flexibility and reliability of a joint 38 on the elongated strip portion 28. The shapes and sizes of the one or more slots 64 may vary between embodiments. In some embodiments, U-shaped slots 70 may have a uniform width 122, whereas in some embodiments the U-shaped slots 70 are wider near the joints 38 than the roots 116. A slot 64 may have one or more (e.g., 1, 2, 3, 4, 5, 6, 7, 8, 9, 10) elongated strip portions 28. As may be appreciated, the slots 64 may be formed by a router, a punch, or other tool. The thickness 120 of the elongated portion may be different than the thickness 124 of the circuit board 26.

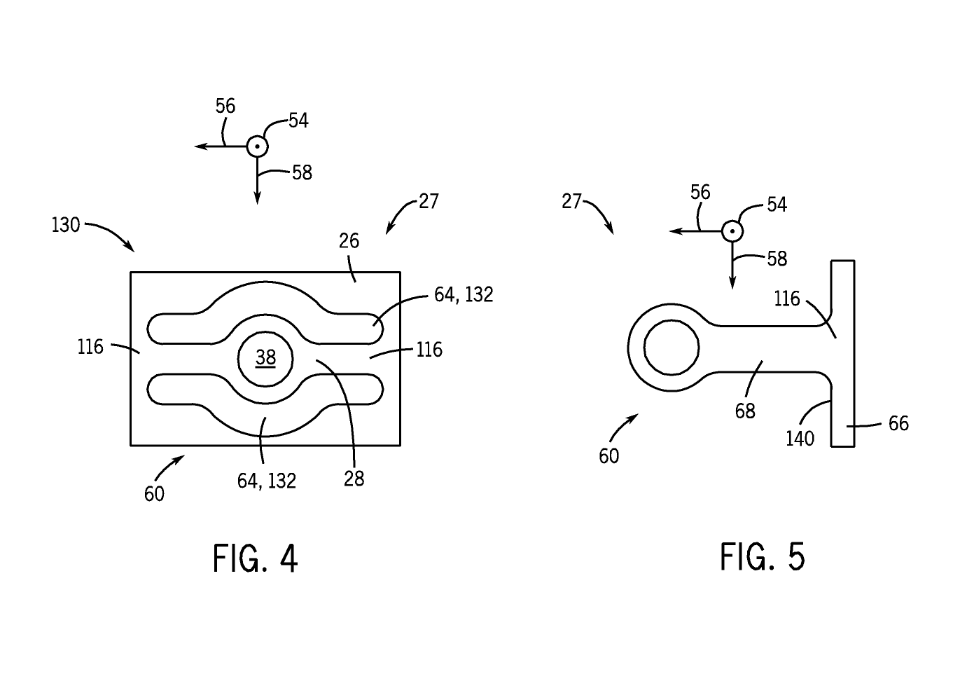

FIGS. 4 and 5 illustrate two presently contemplated embodiments of resilient couplings 27 having elongated strip portions 28; however, the elongated strip portions 28 are not to be limited to these illustrated embodiments. FIG. 4 illustrates an embodiment of a supported elongated strip portion 130. The supported elongated strip portion 130 may have two or more roots 116. The roots 116 may be on the same or different circuit board 26. Some embodiments may have two or more slots 64. In the illustrated embodiment, the joint 38 is on the supported elongated strip portion 130 between two roots 116 and surrounded by two substantially parallel slots 132. Slots 64 may also be triangular, square, curved, or any other shape. Certain shapes of slots 64 may be configured to increase the flexibility along one or more axes 54, 56, and 58. The illustrated supported elongated strip portion 130 may be configured to flex primarily along the Y-axis 54 (e.g., in-out of the page) and Z-axis 58. For example, the supported elongated strip portion 130 may be disposed on the circuit board 26 (FIG. 3) perpendicular to the resistive portion 98, so that the joint 38 has increased flexibility along the Z-axis 58 to be displaced with the expanding or contracting resistive portion 98. In some embodiments, the supported elongated strip portion 130 may have more than two roots 116 and more than two slots 64. The supported elongated strip portion 130 may have approximately 3, 4, 5, 6, 7, 8, 9, or 10 roots and be surrounded by 3, 4, 5, 6, 7, 8, 9, or 10 slots 64, or any combination thereof.

As illustrated in FIGS. 2, 3, and 5, the resilient coupling 27 includes the elongated strip portion 28 with a cantilevered strip portion 68. As described above and illustrated in FIGS. 2 and 3, the cantilevered strip portion 68 may be within the main portion 66 of the circuit board 26 surrounded by a slot 64 (e.g., U-shaped slot 70). The cantilevered strip portion 68 may also protrude away from an edge 140 of the main portion 66 of the circuit board 26. The cantilevered strip portion 68 may have one root 116 and some embodiments may have one or more slots 64. The illustrated embodiment in FIG. 5 does not have a slot 64, because it protrudes from the edge 140 of the circuit board 26.

The present embodiments also include a method of flexing an elongated strip portion of a circuit board relative to a main portion of the circuit board. The elongated strip portion is coupled to a conductive member at a joint, thus coupling the conductive member to the circuit board. The conductive member and/or a component coupled to the conductive member may thermally expand or thermally contract. This thermal expansion and thermal contraction induces stresses on the elongated strip portion and the joint. In some embodiments, the method includes conducting electricity through the component, the conductive member, the joint, and circuitry on the circuit board. The conducted electricity may heat the component, the conductive member, and other parts of the conductive assembly, resulting in thermal expansion. The method may also include measuring usage of the electricity via an electric meter. In some embodiments, the method includes measuring the usage of at least one utility and processing the information relating to the usage via the circuit board of the utility meter.

Technical effects of the present embodiments include coupling a conductive member to a joint (e.g., solder joint) of a resilient coupling (e.g., an elongated strip portion) of a circuit board, so that the elongated strip portion may flex to reduce thermally induced stress in the joint circuit board and/or component. In some embodiments, coupling the conductive member to the circuit board at the joint on the elongated strip portion surrounded by a slot may reduce the thermally induced stress by up to approximately 30 percent for temperature differentials between parts of the conductive assembly of about approximately 50 degrees Celsius. Some embodiments with greater stress reduction may have longer and/or thinner elongated strip portions. The one or more slots surrounding some elongated strip portions may be of the same or different widths. The size of the slots may also affect the amount of stress reduction. The elongated strip portions may be substantially within the main body of the circuit board or may protrude outward from the edge of the circuit board. Furthermore, some elongated strip portions may be supported by the circuit board by two or more roots.

Reducing the thermally induced stress on the joint by any amount may increase the field reliability of the joint. Furthermore, may be desirable to directly integrate components into the circuit board. This may decrease maintenance frequency and costs. A circuit board having the conductive assembly configured to reduce thermally induced stresses may directly integrate components and have a small profile (i.e., thickness). Additionally, this may reduce manufacturing costs due to the ability to directly mount components on the circuit board without additional components or component features to reduce the effect of thermal stresses.

This written description uses examples to disclose the present embodiments, including the best mode, and also to enable any person skilled in the art to practice the present embodiments, including making and using any devices or systems and performing any incorporated methods. The patentable scope of the present embodiments is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

1. A system, comprising:
a utility meter, comprising:
a first conductive member; and
a circuit board coupled to the first conductive member at a first joint, wherein the first joint is disposed along a first elongated strip portion of the circuit board, and the first elongated strip portion is configured to flex relative to a main portion of the circuit board in response to thermal expansion or thermal contraction of the first conductive member or a component coupled to the first conductive member.

2. The system of claim 1, wherein the first elongated strip portion comprises a first cantilevered portion relative to the main portion of the circuit board.

3. The system of claim 2, wherein the first cantilevered portion is surrounded by at least one slot within the main portion of the circuit board.

4. The system of claim 3, wherein the at least one slot comprises a first U-shaped slot around the first cantilevered portion in the main portion of the circuit board.

5. The system of claim 2, wherein the first cantilevered portion protrudes away from an edge of the main portion of the circuit board.

6. The system of claim 1, wherein the first elongated strip portion is surrounded by at least one slot within the main portion of the circuit board.

7. The system of claim 6, wherein the first elongated strip portion is surrounded by a pair of opposing slots within the main portion of the circuit board.

8. The system of claim 1, comprising a second conductive member coupled to the circuit board at a second joint, wherein the second joint is disposed along a second elongated strip portion of the circuit board, and the second elongated strip portion is configured to flex relative to the main portion of the circuit board in response to thermal expansion or thermal contraction of the second conductive member or the component coupled to the second conductive member.

9. The system of claim 8, comprising the component coupled to the first and second conductive members.

10. The system of claim 9, wherein the component comprises a sensor or a heating element, or any combination.

11. The system of claim 1, wherein the utility meter comprises an electric meter.

12. A system, comprising:
a circuit board configured to couple to a first conductive member at a first joint, wherein the first joint is disposed along a first elongated strip portion of the circuit board, and the first elongated strip portion is configured to flex relative to a main portion of the circuit board in response to thermal expansion or thermal contraction of the first conductive member or a component coupled to the first conductive member.

13. The system of claim 12, wherein the first elongated strip portion comprises a first cantilevered portion relative to the main portion of the circuit board.

14. The system of claim 13, wherein the first cantilevered portion is surrounded by at least one slot within the main portion of the circuit board.

15. The system of claim 12, wherein the first elongated strip portion is surrounded by at least one slot within the main portion of the circuit board.

16. The system of claim 12, comprising the component coupled to the first conductive member, wherein the component comprises a sensor or a heating element, or any combination thereof.

17. The system of claim 12, comprising a utility meter having the circuit board.

18. A method, comprising:
flexing a first elongated strip portion of a circuit board relative to a main portion of the circuit board in response to thermal expansion or thermal contraction of a first conductive member or a component coupled to the first conductive member, wherein the first conductive member is coupled to the first elongated strip portion at a first joint.

19. The method of claim 18, comprising:
conducting electricity through the component, the first conductive member, the first joint, and circuitry on the circuit board; and
measuring usage of the electricity via an electric meter.

20. The method of claim 18, comprising:
measuring usage of at least one utility; and
processing information relating to the usage via the circuit board disposed in a utility meter.
